(19) United States
(12) Patent Application Publication
(10) Pub. No.: US 2008/0181100 A1
(43) Pub. Date: Jul. 31, 2008

(54) METHODS AND APPARATUS TO MANAGE NETWORK CORRECTION PROCEDURES

(76) Inventors: Charlie Chen-Yui Yang, Marlboro, NJ (US); Paritosh Bajpay, Edison, NJ (US); Monowar Hossain, Middletown, NJ (US); Dallas McLaughlin, Irving, TX (US)

Correspondence Address: HANLEY, FLIGHT & ZIMMERMAN, LLC, 150 S. WACKER DRIVE, SUITE 2100, CHICAGO, IL, 60606, US

(21) Appl. No.: 11/669,505

(22) Filed: Jan. 31, 2007

(51) Int. Cl. G01R 31/08

(52) U.S. Cl. 370/216

(57) ABSTRACT

A method and apparatus to manage network correction procedures is disclosed. An example method includes receiving an alarm relating to a network anomaly, receiving information relating to the location of the network anomaly, and determining an identity of at least one network element related to the location. The example method also includes ranking a list of corrective procedures, and selecting at least one corrective procedure from the list of corrective procedures.

### FIELD OF THE DISCLOSURE

This disclosure relates generally to communication networks, and, more particularly, to methods and apparatus to manage network correction procedures.

### BACKGROUND

Communication networks for businesses or personal residences typically employ vast numbers of network elements (NEs) that are occasionally susceptible to failure and/or require periodic maintenance. Preventative maintenance procedures may reduce the number of incidents in which NEs fail and/or operate in an inappropriate manner. However, some failures and/or inappropriate NE operation still occur, which requires troubleshooting and analysis of the communication network(s) and/or NEs therein.

A typical communication network includes a number of sub-networks, demarcation points, and end points to facilitate telephony services, high-speed data transmission services, real-time video services, high fidelity audio services, and various combinations of such services. In the event of a service interruption and/or network anomaly, a service provider must determine a course of action to restore the interruption, such as invoking and/or implanting one or more correction procedures. However, the service provider may not know from where the interruption/anomaly is originating and/or whether such issues are caused by a portion of the communication network for which they have control.

Many NEs are processor controlled hardware devices that are addressable and manageable by technicians or network engineers via the Internet, via modem connection, via wireless service (e.g., cell phone) and/or via an intranet managed by the service provider. Additionally, such NEs include an extensive assortment of control commands, built-in test procedures, and/or are capable of being controlled via one or more scripts issued remotely. As a result, even when one or more particular NEs suspected to be causing the network interruption, selecting the most appropriate correction procedure(s) may be difficult.

### BRIEF DESCRIPTION OF THE DRAWINGS

FIG. 1 is a schematic illustration of an example communication network and system to manage network correction procedures.

FIG. 2 is a more detailed illustration of the example network manager of FIG. 1.

FIG. 3 is an example view of a portion of a ticket table of the example system of FIGS. 1 and 2.

FIG. 4 is an example view of a portion of a resolution table of the example system of FIGS. 1 and 2.

FIG. 5 is an example view of output from the example decision rule engine of FIG. 2.

FIG. 6 is a flow diagram representative of example machine readable instructions that may be executed to implement the example system of FIGS. 1 and 2.

FIG. 7 is a schematic illustration of an example computer that may execute the example instructions of FIG. 6 to implement the example system of FIGS. 1 and 2.

### DETAILED DESCRIPTION

A method and apparatus to manage network correction procedures is disclosed. An example method includes receiving an alarm relating to a network anomaly, receiving information relating to the location of the network anomaly, and determining an identity of at least one network element related to the location. The example method also includes ranking a list of corrective procedures, and selecting at least one corrective procedure from the list of corrective procedures.

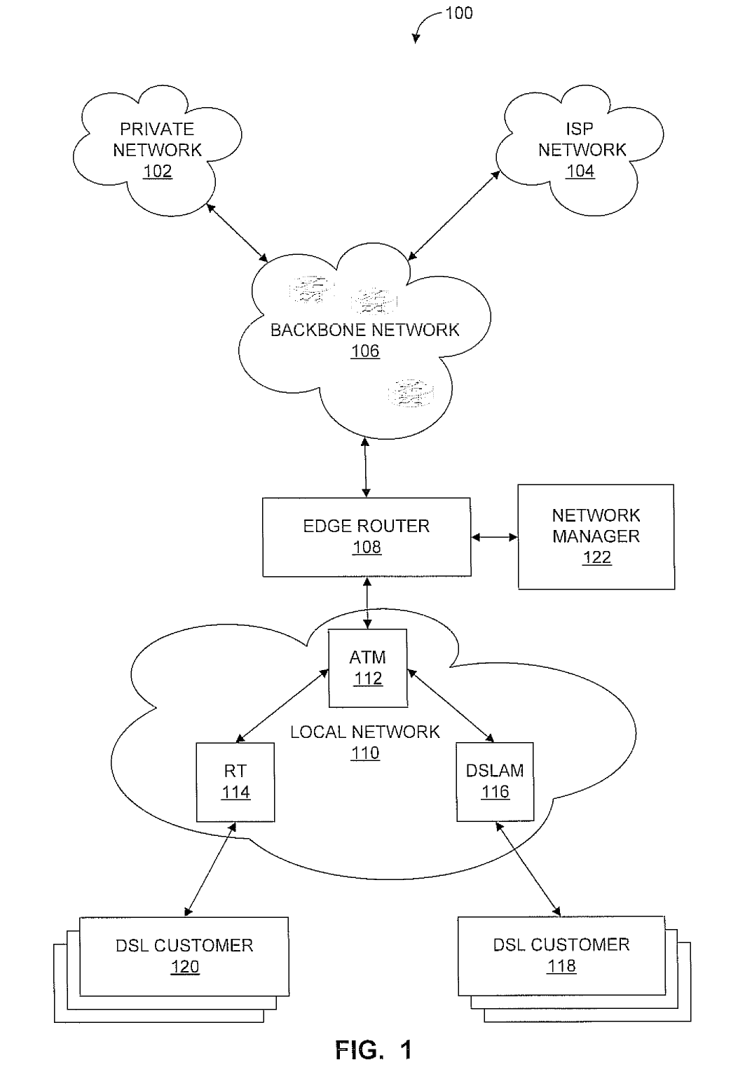

An example communication network 100 is shown in FIG. 1. As described above, the communication network 100 includes various sub-networks, endpoints, and boundaries. In the illustrated example of FIG. 1, the network 100 includes one or more private networks 102, one or more Internet service provider (ISP) networks 104, a backbone network 106, and an edge router 108 to facilitate communication between the boundary of the backbone network 106 and a local network 110. The backbone network 106 typically operates at OC48 (2.4 Gbps) and OC192 (9.6 Gbps), and has several routers therein. On the other hand, the local network 110 of the illustrated example includes one or more asynchronous transfer mode (ATM) switches 112, one or more remote terminals 114, and one or more digital subscriber line access multiplexers (DSLAMs) 116, which facilitate digital subscriber line (DSL) services to one or more DSL customers 118. Persons of ordinary skill in the art will appreciate that the remote terminals 114 also facilitate DSL services to one or more DSL customers 120.

The edge router 108 is an NE that routes data packets between one or more local area networks (LANs) and an ATM backbone network, such as the backbone network 106 of FIG. 1. The edge router 108 is sometimes referred to as an aggregate router and/or a boundary router, such as, for example, the SMS 1800, and/or the SMS10000 by Redback® Networks and/or the ERX by Juniper® Networks. By virtue of its location within an overall network 100, the edge router 108 is particularly well suited to facilitate an early understanding of network 100 health. As discussed in further detail below, the edge router 108 may allow the service provider (e.g., a network engineer, a service technician, etc.) to determine operating parameters of routers within the backbone network 106, operating parameters of the ATM switch 112, operating parameters of the remote terminal (RT) 114 and/or the DSLAM 116, and/or determine various operating parameters of the routers and/or modems associated with the DSL customers 118 and 120.

The example network 100 of FIG. 1 also includes a network manager 122 to, among other things, communicate with the edge router 108 and determine appropriate measures and/or procedures to resolve network interruptions. As discussed in further detail below, the example network manager 122 acquires operational information from the network 100, tests various facets of the example network 100, and applies various rules to solve network interruptions based on past and present network operating conditions.

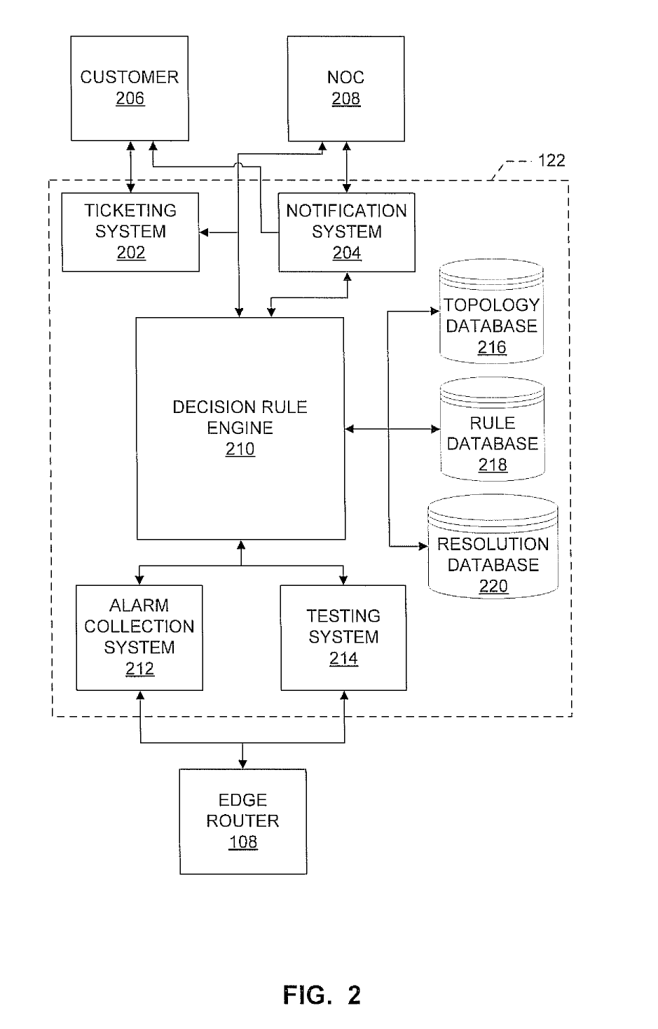

A detailed example implementation of the network manager 122 is shown in FIG. 2 and includes a ticketing system 202 and a notification system 204. In the illustrated example, each of the ticketing system 202 and the notification system 204 are communicatively coupled to one or more customers 206 and a network operations center (NOC) 20S. Access to the network manager 122 is achieved by authorized users, such as network engineers, network technicians, and/or other authorized employees of the service provider. The example network manager 122 also includes a decision rule engine 210, an alarm collection system 212, and a testing system 214. The alarm collection system 212 and the testing system 214 are each communicatively connected to the edge router 108. A topology database 216, a rule database 218, and a resolution database 220 are each communicatively connected to the decision rule engine 210 to provide various types of data that facilitate network (e.g., of the example network 100) interruption resolution (i.e., one or more correction procedures), as discussed in further detail below.

In operation, the alarm collection system 212 is configured to monitor the example network 100 via the edge router 108. The alarm collection system 212 acquires operational information and compares such information to operational thresholds saved in a memory of the alarm collection system 212. For example, the alarm collection system 212 may monitor various ports of the edge router 108 for bandwidth levels, monitor lost data packet values, monitor available internet protocol (IP) addresses of the edge router 108, monitor hardware status conditions, and/or verify one or more IP configuration pool parameters against one or more known configuration templates. In the event that one or more parameters exceeds and/or drops below a threshold value, the alarm collection system passes such error conditions to the decision rule engine 210 for analysis to determine the most appropriate correction procedure(s). As discussed in further detail below, correction procedures may include, but are not limited to, dispatching repair technicians associated with the edge router 108, dispatching repair technicians contracted to service the edge router 108, dispatching repair technicians associated with third party hardware, executing additional test procedures to acquire data, and/or executing one or more scripts designed by the service provider to remotely control one or more NEs of the example network 100. Non-limiting examples of remotely invoked correction procedures are described in further detail below.

The alarm collection system 212 may operate on a periodic basis, a scheduled basis, and/or may be invoked by a user in the NOC 208. While the example alarm collection system 212 is shown to be communicatively coupled to the edge router 108, persons of ordinary skill in the art will appreciate that the alarm collection system 212 may also be communicatively coupled to other NEs of the example network 100. However, cost restraints and/or processing limitations of the alarm collection system 212 may render expansion of monitoring activities impractical. As a result, monitoring of the edge router 108 is typically a suitable technique because network interruptions and/or anomalies by other NEs can be detected by the edge router 108. For example, in the event of one or more DSLAMs failing to operate, such as the example DSLAM 116 of FIG. 1, the alarm collection system 212 may detect that one or more ports of the edge router 108 are not passing any traffic. Accordingly, the resulting alarm induced by this threshold breach places the service provider on notice of a network problem or anomaly.

The decision rule engine 210 may also be alerted of network anomalies in response to customer 206 complaints and/or messages from the NOC 208. For example, the customer 206 may access a web-based interface to log a complaint about slow and/or intermittent DSL service availability. Additionally or alternatively, the customer 206 may access an interactive voice response (IVR) system via telephone and/or wireless telephone (e.g., a cellular telephone) to report such network interruptions to the ticketing system 202. In the illustrated example, the ticketing system 202 generates a service ticket for the complaint/issue and/or forwards the customer to a customer service representative of the NOC 208. The customer service representative may elicit additional details from the customer 206 so that interruption abatement efforts are more likely to succeed. For example, the web-based interface, the IVR system, and/or the customer service representative at the NOC 208 may request the customer's account number, phone number, and/or location information. As such, any information passed to the decision rule engine 210 may also include details that will permit the network manager 122 to determine exact endpoints and/or various NEs, which are between the customer endpoint and the edge router 108 responsible for the network interruptions(s).

In the event that the customer 206 only provides the network manager 122 with a source telephone number, a home address, a name, and/or an account number, the ticketing system passes 202 such information to the decision rule engine 210. The decision rule engine 210 may consult the topology database 216 to reference such provided telephone number, home address, name, and/or account number with a list of NEs associated with that account. For example, customers 206 typically enjoy the benefits of a finite number of known NEs under the service provider's ownership and/or control. Determining which NEs are associated with the customer allows a more focused analysis of problem resolution and saves considerable time.

Persons of ordinary skill in the art will appreciate that the topology database 216 may be updated by employees of the service provider on a regular basis. For example, as new markets are implemented, the NEs associated with those new markets are added to the topology database 216. NE information saved in the topology database 216 may include, but is not limited to, geographic coordinates of the NE (e.g., latitude, longitude, street address, city, state, zip code, etc.), the manufacturer and model number of the NE, the age of the NE, the last service date of the NE, the last failure date of the NE, the IP address of the NE, and/or the last measured capacity of the NE (e.g., the NE was operating at 67% of its full capacity in November of 2006).

NEs, including the edge router 108, are manufactured by a variety of companies that typically conform to at least one industry standard communication protocol. However, each NE may not include the same library of commands to control the features of the NE. Additionally, the topology database 216 may include subroutines, scripts, and/or commands specific to each NE. Queries and/or commands issued to an NE may take the form of, for example, transaction language 1 (TL1) commands, commands formatted in the American Standard Code for Information Interchange (ASCII), standard commands For programmable instrumentation (SCPI), and/or any other command format(s). Access to the NEs may be realized via modems, local area network (LAN) port(s) (e.g., to facilitate a Telnet session), a general purpose interface bus (GPIB), an RS-232 port, and/or a wireless access node that is uniquely addressable. The decision rule engine 210 forwards one or more subroutines, scripts, and/or commands selected from the topology database 216 to the testing system 214 for execution. Without limitation, various procedures, subroutines, test routines, and/or scripts maybe stored in the rule database 218, as discussed in further detail below.

In the illustrated example, the notification system 204 provides the customer 206 and/or the NOC 208 with an acknowledgement that work has begun on the reported network interruption. Additionally, the notification system 204 informs the customer(s) 206 when corrective measures have been completed on the network and/or sub-networks. Such notification messages may be employed via e-mail, pager, short message service (SMS), instant messaging (IM), and/or automated telephone calls. The example notification system 204 may also provide network interruption information to third parties that are responsible for and/or own various facets of the example network 100. For example, in the event that the decision rule engine 210 determines that the network interruption is caused by one or more routers of the backbone network 106, then the notification system 204 may attempt to provide such owners and/or parties chartered with operation of those suspected router(s).

Upon receipt of a ticket, which is indicative of a network 100 interruption and/or anomaly, and/or upon receipt of an alarm condition from the alarm collection system 212, the decision rule engine 210 analyzes the received information for further processing. For example, the users at the NOC 208 and/or the decision rule engine 210 could simply begin to execute any and all known troubleshooting commands of a particular NE in an effort to solve the network interruption. However, in view of the large size of the network, and the complexity of the various NEs, the user at the NOC 208 could have hundreds of potential command candidates from which to choose. Merely applying and/or executing known commands, scripts, and/or subroutines needlessly consumes valuable time, during which the troubled users are still without network services. Furthermore, some of the potential command/subroutine/script candidates may adversely affect other network 100 users that are unaffected by the particular trouble ticket. For example, some of the scripts that may execute in an effort to fix network interruptions require that NEs be totally shut-down and restarted, thereby affecting all customers rather than a select few. On the other hand, a properly selected command, subroutine, and/or script will resolve the particular network interruption while leaving other customers unaffected. Such commands, subroutines, and/or scripts may, instead, only shut down select portions of the NE, such as one or more card slots.

In the illustrated example, the decision rule engine 210 receives the information from the trouble ticket and/or alarm collection system 212 and parses it for location information. Additionally, the decision rule engine 210 parses keywords from the ticket that are indicative of the problem experienced by the user and/or detected by the alarm collection system 212. The decision rule engine 210 uses the location information to query the topology database 216 and derive appropriate NEs that may be causing the network interruption(s). Additionally, the decision rule engine 210 uses the received keywords to formulate a query to the example resolution database 220. The resolution database 220 stores information related to previous network 100 sen-ice calls and the particular solution(s) implemented that resulted in successfully halting or resolving the network interruptions. A database engine of the decision rule engine 210, such as SQL Server by Microsoft®, finds one or more corresponding resolution strategies based on the provided keywords that relate to the network 100 interruption(s). Such resolution strategies are ranked in order based on the number of times that strategy was successfully invoked to accomplish the desired result. The resolution strategies may be provided to a user in the form of a histogram and/or the histogram output may be further analyzed by the decision rule engine 210 based on rules extracted from the rule database 218. The resolution strategy may be, for example, “invoke script B.” In the event that “script B” is the ideal or best known or available resolution or remedy, the decision rule engine 210 may extract the details of “script B” from the topology database 216 or the rule database 218.

In the event that more than one resolution strategy yields the same and/or similar likelihood of success (e.g., by virtue of the number of successful attempts), then the decision rule engine 210 may query the rule database 218 to further narrow the options. For example, one of two example strategies may suggest that a complete power-down of the NE, such as the example edge router 108, will likely solve the network 100 interruption. On the other hand, a second strategy may suggest that only one of the slots and/or cards of the example edge router 108 need to be reset and/or replaced, thereby preventing all other unaffected customers from experiencing any service interruptions(s).

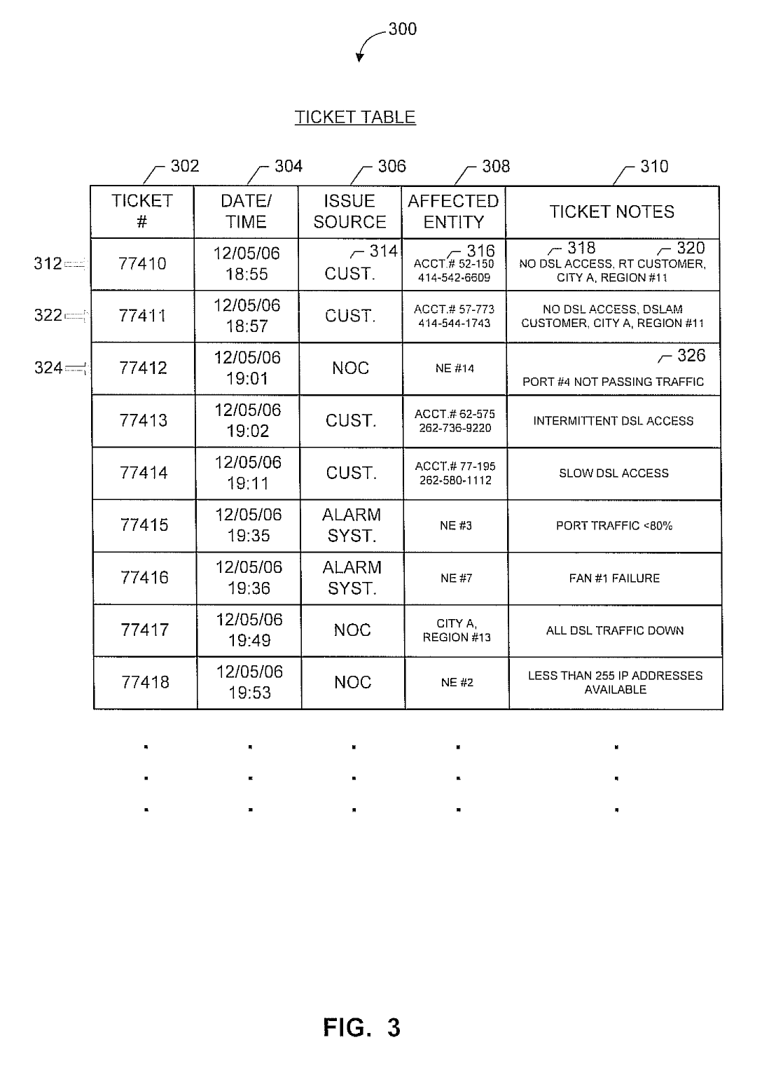

FIG. 3 is a partial view of an example ticket information table 300. The ticketing system 202 may send batches of such tables to the decision rule engine 210 for processing. Additionally or alternatively, the alarm collection system 212 may send a similar table and/or line items as they occur to the decision rule engine 210. Moving forward, the example ticket information table 300 will be described.

In the illustrated example, the ticket information table 300 includes a ticket number column 302, a date/time column 304, an issue source column 306, an affected entity column 308, and a ticket notes column 310. A first row 312 illustrates that the example decision rule engine 210 receives information relating to a customer 314 and the customer's associated telephone number 316. As described above, the decision rule engine 210 uses the customer's telephone number 314 during a query to the topology database 216 to determine the nearest NEs that are likely to service this particular customer. Instead of, and/or in addition to the provided telephone number 316, the affected entity column 308 may include an account number, an address, and/or the nearest intersecting streets. The first row 312 also illustrates that the customer complained of “no DSL access” 318 and that the customer was configured to receive DSL services via a remote terminal (RT) 320. Such advanced knowledge of how DSL services are provisioned to the customer (e.g., via RTs, via DSLAMs, etc.) allows more efficient troubleshooting.

A second row 322 illustrates another example ticket entry of the ticket information table 300, in which the customer receives DSL services via a DSLAM. As such, the example decision rule engine 210 may more accurately retrieve a list of suspect NEs from the topology database 216. In the event that the NOC 208 enters a ticket into the ticketing system 202, the user (e.g., a network engineer, a network technician, etc.) may provide more specific information relating to which NE is believed to be causing the interruption. For example, a third row 324 of the example ticket table 300 illustrates the NOC user identified that NE #14 was not passing traffic along port #4 (326).

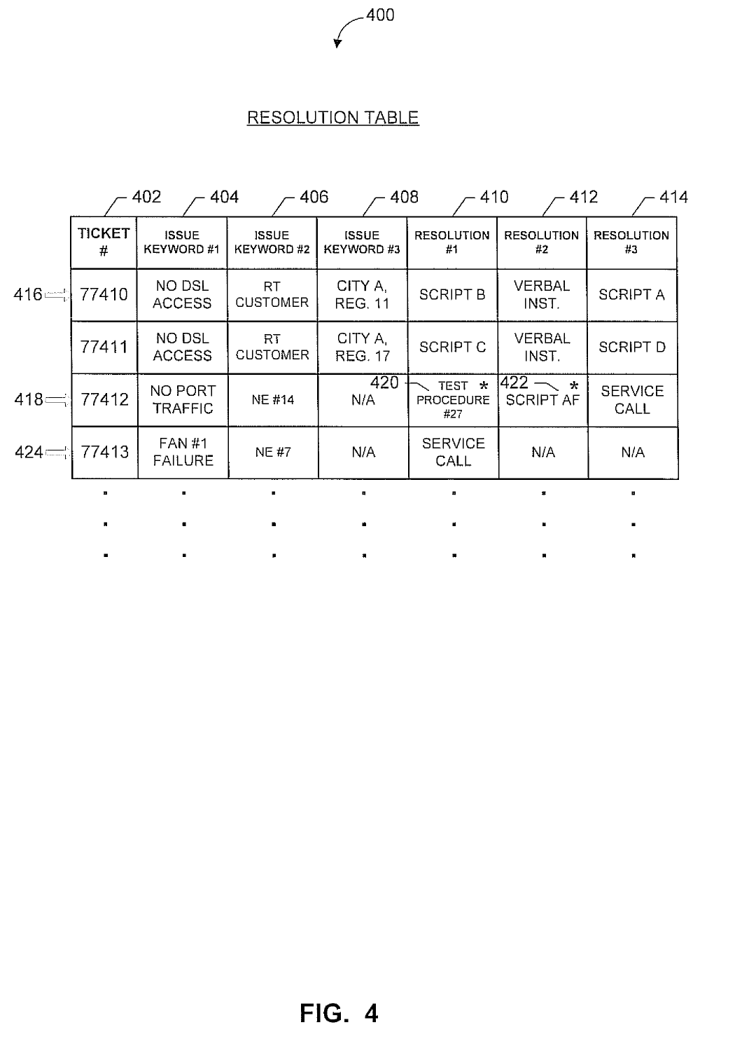

FIG. 4 is a partial view of an example resolution table 400 generated after the decision rule engine 210 queries the resolution database 220. In the illustrated example, the resolution table 400 includes a ticket number column 402, a first issue keyword column 404, a second issue keyword column 406, and a third issue keyword column 408. Persons of ordinary skill in the art will appreciate that a database query may return more focused results if provided with more input data. While the example resolution table 400 of FIG, 4 illustrates three columns of potential keywords that are indicative of the network problem, greater or fewer columns may alternatively be employed.

The example resolution table 400 also includes a first resolution column 410, a second resolution column 412, and a third resolution column 414. The decision rule engine 210 query returns potential resolution candidates (i.e., correction procedure(s)) in the resolution columns (410, 412, 414) in order of rank. For example, a first row 416 includes a first issue keyword (phrase) “No DSL Access,” a second issue keyword “RT Customer,” and a third issue keyword “City A, Region #11.” The query results from the provided keywords include “Script B” as the highest ranked option (e.g., a best known or available ranking remedy or resolution), “Verbal Instructions” as the next highest ranked option, and “Script A” as the lowest of the three listed resolution options. Persons of ordinary skill in the art will appreciate that greater or fewer results may be incorporated, as needed. Script B was listed first because the resolution database 220 included that particular course of action the greatest number of times when trying to solve an issue of “No DSL Access” for a customer using a remote terminal in city A, region #11.

A second row 418 illustrates a separate ticket item in which the keyword “No Port Traffic” and “NE #14” was used in a query to the resolution database 220. However, the first resolution 420 and the second resolution 422 recommendation each have the same rank, as identified by the asterisk (*). As discussed in further detail below, such equal rankings are further analyzed by the example decision rule engine 210 in view of the contents from the rule database 218. A third row 424 illustrates that, after a query using keywords “Fan #1 Failure” and “NE #7,” only a single resolution option of “Service Call” is provided.

One example corrective procedure of the rule database 218 is invoked upon determining that one or more ports on a DSL edge router is down and not passing traffic, thereby resulting in the subscriber's Internet connection being dropped. The example corrective procedure sends a request to the testing system 214 to access the edge router 108 and retrieve an operational log. Evaluation of the log allows the testing system 214 to determine whether the interface is down and/or otherwise malfunctioning. Additionally, the log allows the testing system 214 to determine whether the malfunction(s) is (are) caused by a single interface card, one or more interface cards, or a general fault with the entire edge router 108. If the log is clear of local issues, then the example corrective procedure causes the testing system 214 to bounce the suspected port. Persons of ordinary skill in the art will appreciate that if the port fails to recover from the bounce, then the malfunction is deemed to be a circuit (i.e., hardware) issue. As such, the corrective action instructs the testing system 214 and/or the decision rule engine 210 to inform a workcenter (e.g., a maintenance crew) to replace and/or repair the affected circuit.

Another example corrective procedure of the rule database 218 is invoked upon determining that a port of the edge router 108 is collecting a high rate of errors, thereby causing the subscriber's Internet connection to be impacted by high latency effects. The example corrective procedure sends a request to the testing system 214 to attempt a telnet and/or an out-of-band instruction to the edge router 108. The testing system 214 then attempts a ping and/or a trace operation to the edge router 108 to determine proper connectivity to the example network 100. Additionally, the example corrective procedure may wait for a predetermined amount of time to see if the edge router 108 recovers and/or otherwise restores itself. The testing system 214 then monitors various ports to confirm that subscribers/customers are reconnecting to the edge router 108. Based on the results of the telnet and subsequent ping(s) and/or trace commands, the problem is identified as either a software or a hardware issue, thereby allowing the appropriate workcenter and/or service technicians to be dispatched.

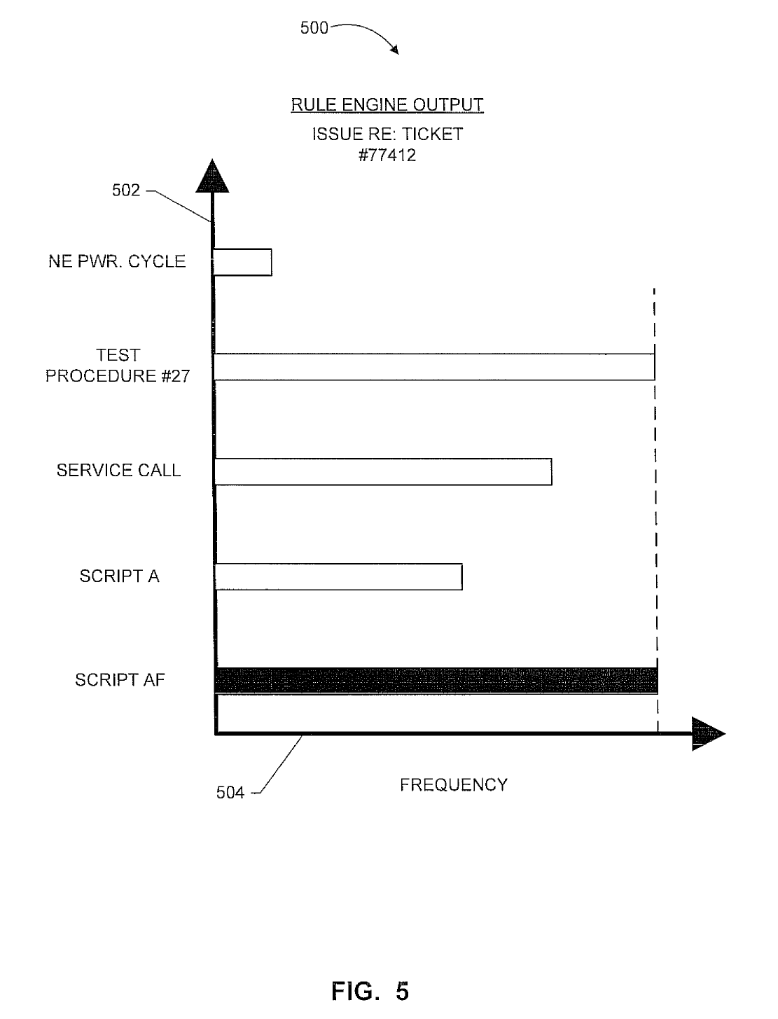

FIG. 5 is a view of example output histogram 500 from the decision rule engine 210. The illustrated example histogram 500 includes a vertical axis 502 listing various resolution procedures that may solve the problem related to the keywords provided in the query. Additionally, the example histogram 500 includes a horizontal axis 504 to illustrate a relative frequency for each of the various resolution procedures shown in the vertical axis 502. In particular, the example histogram 500 corresponds to example ticket number 77413, which is shown as row 418 in FIG. 4. In the illustrated example histogram 500, resolution “Test Procedure 27” and “Script AF” both received an equal ranking, but the decision rule engine 210 invoked a query to the rule database 218 to differentiate between the two options. More specifically, the rule database 218 included an example rule that prefers “Script AF” over other test procedures, scripts, and/or subroutines because, for example, “Script AF” has less of an impact on customers of the network 100. On the other hand, “Test Procedure 27” may not be favored because it resets a greater number of card slots within the NE, such as the example edge router 108, thereby causing many more customers to experience a service interruption. The output of the decision rule engine 210 may be provided to the NOC 208 users (e.g., the network engineers, the network technicians, etc.) and/or to the customer(s) 206 via the notification system 204. While the users at the NOC 208 typically receive results and/or feedback from the decision rule engine 210 in full detail, the example notification system 204 may strip out and/or reformat the results for the customer. In other words, the notification system 204 may translate the output shown in FIG. 5 as “Your network interruption has ended, please attempt to use your DSL service again. We apologize for the inconvenience.”

In the illustrated example, the output of the decision rule engine 210 is also passed to the testing system 214 to execute the selected resolution. The testing system 214 may query the rule database 218 to determine appropriate testing protocols, commands and/or scripts. Similarly, the testing system 214 may query the topology database 216 to determine similar testing protocols if they are not present in the rule database 218, and/or the testing system 214 may query the topology database 216 to retrieve specific information about the suspected NE(s). As discussed above, such specific information specific to each NE that may be stored in the topology database 216 includes the NE location, the NE IP address, the NE age, the NE model number, etc.

Upon completion of implementing the selected resolution, the decision rule engine 210 updates the resolution database 220. As the example network manager 122 is used more often, the resolution database 220 becomes more robust and better able to pinpoint the best resolution for a particular problem (i.e., a particular set of keywords).

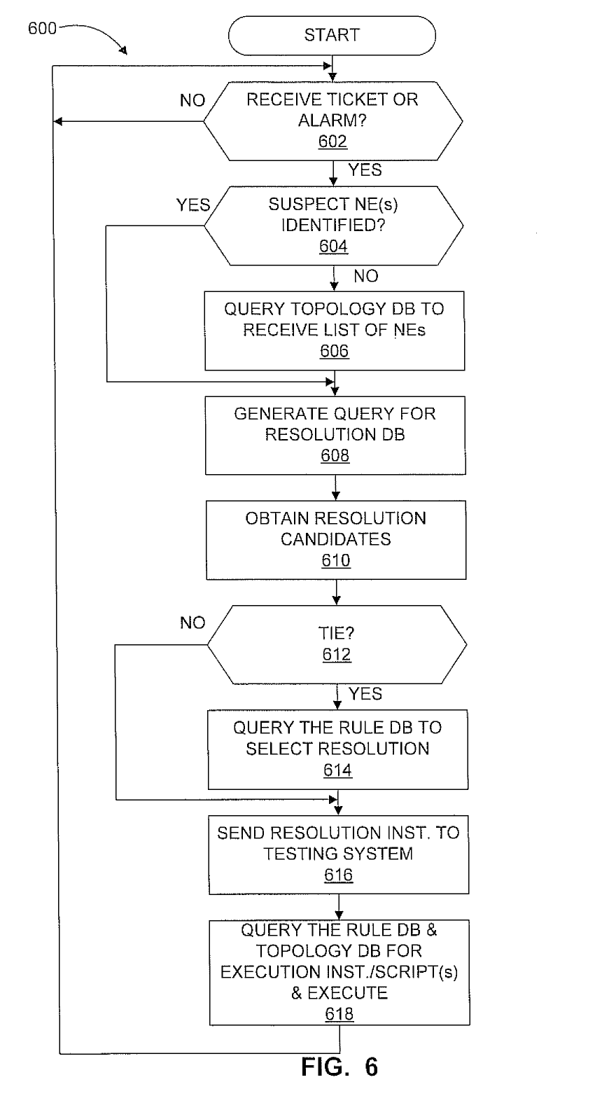

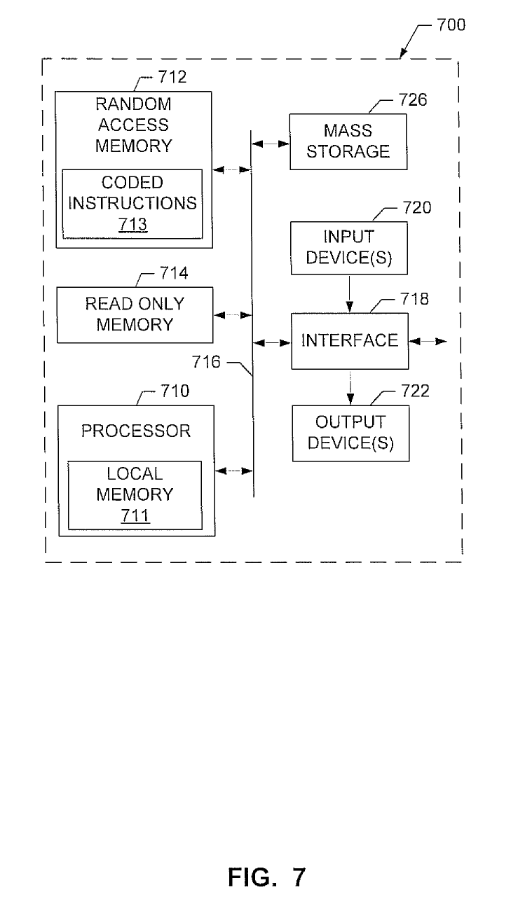

A flowchart representative of example machine readable instructions for implementing methods and apparatus to manage network correction procedures is shown in FIG. 6. In this example, the machine readable instructions comprise a program for execution by: (a) a processor such as the processor 710 shown in FIG. 7, which may be part of a computer, (b) a controller, and/or (c) any other suitable processing device. The program may be embodied in software stored on a tangible medium such as, for example, a flash memory, a CD-ROM, a floppy disk, a hard drive, a digital versatile disk (DVD), or a memory associated with the processor 710, but persons of ordinary skill in the art will readily appreciate that the entire program and/or parts thereof could alternatively be executed by a device other than the processor 710 and/or embodied in firmware or dedicated hardware in a well known manner. For example, any or all of the example network manager 122, the ticketing system 202, the notification system 204, the decision rule engine 210, the alarm collection system 212, the testing system 214, the topology database 216, the rule database 218, and/or the resolution database 220 could be implemented by software, hardware, and/or firmware (e.g., it maybe implemented by an application specific integrated circuit (ASIC), a programmable logic device (PLD), a field programmable logic device (FPLD), discrete logic, etc.).

Also, some or all of the machine readable instructions represented by the flowchart of FIG. 6 maybe implemented manually. Further, although the example program is described with reference to the flowchart illustrated in FIG. 6, persons of ordinary skill in the art will readily appreciate that many other methods of implementing the example machine readable instructions may alternatively be used. For example, the order of execution of the blocks may be changed, and/or some of the blocks described maybe changed, substituted, eliminated, or combined.

The example process 600 of FIG. 6 begins at block 602 where the network manager 122 determines whether a ticket has been received, and/or whether an alarm has been triggered. More specifically, the ticketing system 202 of the example network manager receives work orders and/or complaints from customers 206 of the example network 100 when communication interruptions occur. The tickets contain information relating to the network interruption, including, but not limited to, the name of the customer, the customer's address, the customer's account number, the customer's telephone number, the observed problem(s) (e.g., reduced or no DSL services), and/or the duration of the network interruption. Similarly, the example alarm collection system 212 collects information relating to communication interruptions and forwards associated information to the decision rule engine 210 (block 602).

If ticket or alarm information is received at block 602, the decision rule engine 210 parses the ticket information and/or alarm information from the alarm collection system 212 to determine whether one or more specific NEs is identified as potentially suspect (block 604). If the ticket and/or alarm information does not contain an identity (e.g., does not identify a suspect NE) of one or more specific NEs (e.g., such as a NE number, an NE IP address, etc.), then the decision rule engine 210 queries the topology database 216 to attempt to reconcile provided ticket information and/or alarm information with one or more specific NEs (block 606). For example, if the ticket information includes a customer's telephone number, then the decision rule engine 210 attempts to find one or more NEs listed in the topology database 216 that service that particular telephone number. Persons having ordinary skill in the art will appreciate that not all provided ticket information will necessarily result in a match of one or more specific NEs.

The decision rule engine 210 generates a query for the resolution database 220 by supplying one or more keywords extracted from the ticket and/or the alarm (block 608). In the illustrated example, such keywords are provided by customers 206 when submitting their complaint on a web-based system, an IVR system, or when speaking with a customer service representative. Persons having ordinary skill in the art will appreciate that the selections that a customer can make may be constrained to a discrete number of canned terms and/or phrases to promote an efficient database. In other words, if the consumer is attempting to convey an issue with intermittent DSL services via a web-based complaint form, then the form may employ a drop-down menu of potential complaints. As such, the user may only select nomenclature that will be recognized by the database rather than words, descriptions, and/or other nomenclature that the customer may use during normal speech (e.g., “My internet connection doesn't work all the time” versus “Intermittent DSL Access.”). Similarly, if the customer 206 is speaking with customer service representatives at the NOC 208, then the representatives may translate the customer's speech into terms appropriate for the example network manager 122.

The example decision rule engine 210 executes the query to obtain one or more resolutions that are likely to solve the network interruption (block 610). In the illustrated example, the resolution database 220 returns resolution candidates (see columns 410, 412, and 414 of FIG. 4) in a resolution table 400. Persons having ordinary skill in the art will appreciate that only three such resolution candidates are shown for ease of explanation, however more or fewer resolution candidates may be returned from the query and ranking operation at block 610. The resolution candidates are ranked in order of most frequently used resolution, to the least frequently used resolution (block 610). In the event of a tie between two or more resolution candidates (block 612), the decision rule engine 210 queries the rule database 218 to determine which resolution (i.e., which one or more commands, scripts, and/or subroutines) should be selected to eliminate the network interruption (block 614). In particular, the rule database 218 may be populated with various rules, guidelines, and/or best practices relating to the communication network. Such example rules may take into effect the practicality of preserving network services for as many customers as possible, while simultaneously attempting to solve network interruption issues for a select few number of customers. In one example, solving the network interruption issues requires performing a reset on an NE. However, similar results may be realized by performing a reset on smaller sections of the NE (e.g., individual slots and/or cards of the NE), rather than resetting the whole device.

After determining the appropriate resolution candidate to use in an effort to solve the network interruption issue(s) (block 614), the decision rule engine 210 passes the resolution instructions to the testing system 214 (block 616). The testing system 214 may further query the topology database 216 and/or the rule database 218 to extract specific commands, scripts, and/or subroutines specific to the NE to be controlled, and then execute the resolution (block 618). Persons having ordinary skill in the art will appreciate that the testing system 214 may facilitate testing and/or automated testing across multiple facets of the example network 100 (e.g., end-to-end testing from consumer premises equipment (CPE) through DSL networks and/or backbone network(s)). Without limitation, the testing system 214 may employ various pieces of test equipment throughout the network 100 to acquire other operational data. Operational data acquired by the test equipment may include, but is not limited to, upstream data rates, downstream data rates, data rates per port, bit error rates, and/or ambient conditions (e.g., temperature and/or humidity of equipment in remote offices).

FIG. 7 is a block diagram of an example computer or processor system 700 capable of executing the example machine recordable instructions represented by the flowchart of FIG. 6 to implement the apparatus and methods disclosed herein. The computer or processor system 700 can be, for example, a server, a personal computer, a laptop, a PDA, or any other type of computing device.

The computer or processor system 700 of the instant example includes a processor 710 such as a general purpose programmable processor. The processor 710 includes a local memory 711, and executes coded instructions 713 present in the local memory 711 and/or in another memory device. The processor 710 may execute, among other things, the example process 600 illustrated in FIG. 6. The processor 710 may be any type of processing unit, such as a microprocessor from the Intel® Centrino® family of microprocessors, the Intel® Pentium® family of microprocessors, the Intel® Itanium® family of microprocessors, the Intel XScale® family of processors, and/or the Motorola® family of processors. Of course, other processors from other families are also appropriate.

The processor 710 is in communication with a main memory including a volatile memory 712 and a non-volatile memory 714 via a bus 716. The volatile memory 712 may be implemented by Synchronous Dynamic Random Access Memory (SDRAM), Dynamic Random Access Memory (DRAM), RAMBUS Dynamic Random Access Memory (RDRAM) and/or any other type of random access memory device. The non-volatile memory 714 may be implemented by flash memory and/or any other desired type of memory device. Access to the main memory 712, 714 is typically controlled by a memory controller (not shown) in a conventional manner,

The computer 700 also includes a conventional interface circuit 718. The interface circuit 718 may be implemented by any type of well known interface standard, such as an Ethernet interface, a universal serial bus (USB), and/or a third generation input/output (3GIO) interface.

One or more input devices 720 are connected to the interface circuit 718. The input device(s) 720 permit a user to enter data and commands into the processor 710. The input device(s) can be implemented by, for example, a keyboard, a mouse, a touchscreen, a track-pad, a trackball, isopoint and/or a voice recognition system.

One or more output devices 722 are also connected to the interface circuit 718. The output devices 722 can be implemented, for example, by display devices (e.g., a liquid crystal display, a cathode ray tube display (CRT), a printer and/or speakers). The interface circuit 718, thus, typically includes a graphics driver card.

The interface circuit 718 also includes a communication device such as a modem or network interface card to facilitate exchange of data with external computers via a network (e.g., an Ethernet connection, a digital subscriber line (DSL), a telephone line, coaxial cable, a cellular telephone system, etc.).

The computer 700 also includes one or more mass storage devices 726 for storing software and data. Examples of such mass storage devices 726 include floppy disk drives, hard drive disks, compact disk drives and digital versatile disk (DVD) drives. The mass storage device 726 may implement the memory of the example topology database 216, the example rule database 218, and/or the example resolution database 220.

At least some of the above described example methods and/or apparatus are implemented by one or more software and/or firmware programs running on a computer processor. However, dedicated hardware implementations including, but not limited to, application specific integrated circuits, programmable logic arrays and other hardware devices can likewise be constructed to implement some or all of the example methods and/or apparatus described herein, either in whole or in part. Furthermore, alternative software implementations including, but not limited to, distributed processing or component/object distributed processing, parallel processing, or virtual machine processing can also be constructed to implement the example methods and/or apparatus described herein.

It should also be noted that the example software and/or firmware implementations described herein are optionally stored on a tangible storage medium, such as: a magnetic medium (e.g., a magnetic disk or tape); a magneto-optical or optical medium such as an optical disk; or a solid state medium such as a memory card or other package that houses one or more read-only (non-volatile) memories, random access memories, or other re-writable (volatile) memories; or a signal containing computer instructions. A digital file attached to e-mail or other information archive or set of archives is considered a distribution medium equivalent to a tangible storage medium. Accordingly, the example software and/or firmware described herein can be stored on a tangible storage medium or distribution medium such as those described above or successor storage media.

To the extent the above specification describes example components and functions with reference to particular standards and protocols, it is understood that the scope of this patent is not limited to such standards and protocols. For instance, each of the standards for Internet and other packet switched network transmission (e.g., Transmission Control Protocol (TCP)/Internet Protocol (IP), User Datagram Protocol (UDP)/IP, HyperText Markup Language (HTML), HyperText Transfer Protocol (HTTP)) represent examples of the current state of the art. Such standards are periodically superseded by faster or more efficient equivalents having the same general purpose. Accordingly, replacement standards and protocols having the same general purpose are equivalents to the standards/protocols mentioned herein, and contemplated by this patent, are intended to be included within the scope of the accompanying claims.

This patent contemplates examples wherein a device is associated with one or more machine readable mediums containing instructions, or receives and executes instructions from a propagated signal so that, for example, when connected to a network environment, the device can send or receive voice, video or data, and communicate over the network using the instructions. Such a device can be implemented by any electronic device that provides voice, video and/or data communication, such as a telephone, a cordless telephone, a mobile phone, a cellular telephone, a Personal Digital Assistant (PDA), a set-top box, a computer, and/or a server.

Additionally, although this patent discloses example software or firmware executed on hardware and/or stored in a memory, it should be noted that such software or firmware is merely illustrative and should not be considered as limiting. For example, it is contemplated that any or all of these hardware and software components could be embodied exclusively in hardware, exclusively in software, exclusively in firmware or in some combination of hardware, firmware and/or software. Accordingly, while the above specification described example methods and articles of manufacture, persons of ordinary skill in the art will readily appreciate that the examples are not the only way to implement such methods and articles of manufacture. Therefore, although certain example methods, apparatus and articles of manufacture have been described herein, the scope of coverage of this patent is not limited thereto. On the contrary, this patent covers all methods, apparatus and articles of manufacture fairly falling within the scope of the appended claims either literally or under the doctrine of equivalents.

What is claimed s:

1. A method for invoking network correction procedures, comprising:
receiving an alarm relating to a network anomaly;
receiving information relating to the location of the network anomaly;
determining an identity of at least one network element related to the location;
ranking a list of corrective procedures; and
selecting at least one corrective procedure from the list of corrective procedures.

2. A method as defined in claim 1, wherein ranking the list of corrective procedures comprises:
receiving at least one keyword describing the network anomaly;
querying a resolution database with the at least one keyword and the information relating to the location of the network anomaly;
receiving the list of corrective procedures; and
arranging the list of corrective procedures based on the number of times each procedure was used.

3. A method as defined in claim 1, wherein receiving the alarm comprises receiving a message that at least one predetermined threshold has been triggered, the predetermined threshold indicative of network performance.

4. A method as defined in claim 1, wherein the information received relating to the location of the network anomaly comprises at least one of a zip-code, an address, a street intersection, a latitude, a longitude, a customer telephone number, or a customer account number.

5. A method as defined in claim 1, wherein determining the identity of the at least one network element comprises querying a topology database, the query providing the information relating to the location of the network anomaly.

6. A method as defined in claim 1, wherein receiving the alarm comprises receiving a trouble ticket in response to a customer complaint.

7. A method as defined in claim 1, wherein selecting the at least one corrective procedure comprises querying a rule database to determine a preference for one of the at least one corrective procedure.

8. A method as defined in claim 1, further comprising determining if two or more corrective procedures have the same rank.

9. A method as defined in claim 8, further comprising performing a query on a rule database to determine a preference for one of the two or more corrective procedures.

10. A method as defined in claim 1, wherein selecting the at least one corrective procedure comprises determining a customer impact of the at least one corrective procedure.

11. A method as defined in claim 10, further comprising selecting the at least one corrective procedure having the lowest customer impact.

12. A system for invoking network correction procedures, comprising:
a network manager to receive a notification message indicative of a network error associated with a network;
a decision rule engine to receive the notification message and rank a list of correction procedures related to repair of the network error, wherein the decision rule engine is to invoke a rule database to select at least one of the correction procedures; and
a testing system to execute the at least one correction procedure.

13. A system for invoking network correction procedures as defined in claim 12, wherein the network manager comprises an alarm collection system to monitor the network for one or more violations of one or more network performance thresholds, wherein each violation is indicative of the network error.

14. A system for invoking network correction procedures as defined in claim 12, further comprising a topology database to determine an identity of at least one network element (NE) associated with the network error.

15. A system for invoking network correction procedures as defined in claim 14, wherein the topology database returns the NE identity based on information indicative of the location of the network error.

16. A system for invoking network correction procedures as defined in claim 15, wherein the information indicative of the location of the network error comprises at least one of a zip-code, an address, a street intersection, a latitude, a longitude, a customer telephone number, or a customer account number.

17. A system for invoking network correction procedures as defined in claim 12, further comprising a resolution database to store a plurality of network correction procedures.

18. A system for invoking network correction procedures as defined in claim 17, wherein the resolution database comprises a count value indicative of successful implementations for each one of the plurality of network correction procedures.

19. A system for invoking network correction procedures as defined in claim 18, wherein each one of the plurality of network correction procedures is associated with at least one keyword.

20. A system for invoking network correction procedures as defined in claim 19, wherein the at least one keyword is indicative of at least one of a network element, a network element location, an error locality, or a failure description.

21. A system for invoking network correction procedures as defined in claim 12, wherein the rule database comprises a plurality of network correction procedures.

22. A system for invoking network correction procedures as defined in claim 21, wherein the plurality of network correction procedures comprises at least one of a network element command, a subroutine, or a script.

23. An article of manufacture storing machine readable instructions that, when executed, cause a machine to:
receive an alarm relating to a network anomaly;
receive information relating to the location of the network anomaly;
determine an identity of at least one network element related to the location;
rank a list of corrective procedures; and
select at least one corrective procedure from the list of corrective procedures.

24. An article of manufacture as defined in claim 23, wherein the machine readable instructions, when executed, cause the machine to:
receive at least one keyword describing the network anomaly;
query a resolution database with the at least one keyword and the information relating to the location of the network anomaly;
receive the list of corrective procedures; and
arrange the list of corrective procedures based on the number of times each procedure was used.

25. An article of manufacture as defined in claim 23, wherein the machine readable instructions, when executed, cause the machine to receive a message that at least one predetermined threshold has been triggered, wherein the predetermined threshold is indicative of network performance.

26. An article of manufacture as defined in claim 23, wherein the machine readable instructions, when executed, cause the machine to receive location information of at least one of a zip-code, an address, a street intersection, a latitude, a longitude, a customer telephone number, or a customer account number.

27. An article of manufacture as defined in claim 23, wherein the machine readable instructions, when executed, cause the machine to query a topology database to determine an identity of the at least one network element, wherein the query provides the information relating to the location of the network anomaly.

28. An article of manufacture as defined in claim 23, wherein the machine readable instructions, when executed, cause the machine to receive a trouble ticket in response to a customer complaint.

29. An article of manufacture as defined in claim 23, wherein the machine readable instructions, when executed, cause the machine to query a rule database to determine a preference for one of the at least one corrective procedures.

30. An article of manufacture as defined in claim 23, wherein the machine readable instructions, when executed, cause the machine to determine if two or more corrective procedures have the same rank.

31. An article of manufacture as defined in claim 30, wherein the machine readable instructions, when executed, cause the machine to perform a query on a rule database to determine a preference for one of the two or more corrective procedures.

32. An article of manufacture as defined in claim 23, wherein the machine readable instructions, when executed, cause the machine to determine a customer impact of the at least one corrective procedure.

33. An article of manufacture as defined in claim 32, wherein the machine readable instructions, when executed, cause the machine to select the at least one corrective procedure having the lowest customer impact.
